(19) United States
(12) Patent Application Publication
(10) Pub. No.: US 2021/0193852 A1
(43) Pub. Date: Jun. 24, 2021

(54) SUBTRACTIVE METALLIZATION FOR SOLAR CELLS

(71) Applicant: SunPower Corporation, San Jose, CA (US)

(72) Inventors: Hung-Ming Wang, San Jose, CA (US); Raphael Manalo, San Jose, CA (US)

(21) Appl. No.: 16/723,628

(22) Filed: Dec. 20, 2019

(51) Int. Cl. H01L 31/0352; H01L 31/028; H01L 31/18; H01L 23/00

(52) U.S. Cl. CPC H01L 31/03529; H01L 24/29; H01L 31/18; H01L 31/0284

(57) ABSTRACT

Subtractive metallization approaches for fabricating solar cells, and the resulting solar cells, are described. In an example, a solar cell includes a semiconductor region in or above a substrate. A metal foil portion can include an adhesive layer thereon. The adhesive layer is above the semiconductor region and has an opening therein exposing a portion of the semiconductor region. A conductive material is on and electrically coupled to the portion of the semiconductor region exposed by the opening in the adhesive layer. The conductive material is further on and electrically coupled to the metal foil portion.

### TECHNICAL FIELD

Embodiments of the present disclosure are in the field of renewable energy and, in particular, include subtractive metallization approaches for fabricating solar cells, and the resulting solar cells.

### BACKGROUND

Photovoltaic cells, commonly known as solar cells, are well known devices for direct conversion of solar radiation into electrical energy. Generally, solar cells are fabricated on a semiconductor wafer or substrate using semiconductor processing techniques to form a p-n junction near a surface of the substrate. Solar radiation impinging on the surface of, and entering into, the substrate creates electron and hole pairs in the bulk of the substrate. The electron and hole pairs migrate to p-doped and n-doped regions in the substrate, thereby generating a voltage differential between the doped regions. The doped regions are connected to conductive regions on the solar cell to direct an electrical current from the cell to an external circuit coupled thereto.

Electrical conversion efficiency is an important characteristic of a solar cell as it is directly related to the capability of the solar cell to generate power; with higher efficiency providing additional value to the end customer; and, with all other things equal, higher efficiency also reduces manufacturing cost per Watt. Likewise, simplified manufacturing approaches provide an opportunity to lower manufacturing costs by reducing the cost per unit produced. Accordingly, techniques for increasing the efficiency of solar cells and techniques for simplifying the manufacturing of solar cells are generally desirable.

### BRIEF DESCRIPTION OF THE DRAWINGS

FIG. 1 illustrates a cross-sectional view and corresponding plan view of a solar cell, in accordance with an embodiment of the present disclosure.

FIG. 2 illustrates a cross-sectional view and corresponding plan view of another solar cell, in accordance with another embodiment of the present disclosure.

FIG. 3A illustrates a cross-sectional view and corresponding plan view of another solar cell, in accordance with another embodiment of the present disclosure.

FIG. 3B illustrates a cross-sectional view and corresponding plan view of yet another solar cell, in accordance with another embodiment of the present disclosure.

FIG. 4 is a flowchart including various operations in a method of fabricating a solar cell, in accordance with an embodiment of the present disclosure.

FIGS. 5A-5G illustrate cross-sectional views and corresponding plan views representing various operations in a method of fabricating a solar cell, in accordance with an embodiment of the present disclosure.

FIG. 6 is a flowchart including various operations in another method of fabricating a solar cell, in accordance with another embodiment of the present disclosure.

FIGS. 7A-7E illustrate cross-sectional views and corresponding plan views representing various operations in another method of fabricating a solar cell, in accordance with another embodiment of the present disclosure.

FIGS. 8A-8D illustrate example semiconductor substrates fabricated using methods or approaches described herein, according to some embodiments.

### DETAILED DESCRIPTION

The following detailed description is merely illustrative in nature and is not intended to limit the embodiments or the application and uses of such embodiments. As used herein, the word “exemplary” means “serving as an example, instance, or illustration.” Any implementation described herein as exemplary is not necessarily preferred or advantageous over other implementations. Furthermore, there is no intention to be bound by any expressed or implied theory presented in the preceding technical field, background, brief summary or the following detailed description.

References to “one embodiment” or “an embodiment.” do not necessarily refer to the same embodiment. Particular features, structures, or characteristics can be combined in any suitable manner consistent with this disclosure.

Terminology. The following paragraphs provide definitions and/or context for terms found in this disclosure (including the appended claims):

“Comprising” is open-ended term does not foreclose additional structure or steps.

“Configured to” connotes structure by indicating that a device, such as a unit or a component, includes structure that performs a task or tasks during operation, such structure is configured to perform the task even when the device is not currently operational (e.g., is not on/active). A device “configured to” perform one or more tasks is expressly intended to not invoke a means or step plus function interpretations under 35 U.S.C. § 112, (f) or sixth paragraph.

“First,” “second,” etc. terms are used as labels for nouns that they precede, and do not imply any type of ordering (e.g., spatial, temporal, logical, etc.). For example, reference to a “first” solar cell does not necessarily mean such solar cell in a sequence; instead the term “first” is used to differentiate this solar cell from another solar cell (e.g., a “second” solar cell).

“Coupled” refers to elements, features, structures or nodes unless expressly stated otherwise, that are or can be directly or indirectly joined or in communication with another element/node/feature, and not necessarily directly mechanically joined together.

“Inhibit” describes reducing, lessening, minimizing or effectively or actually eliminating something, such as completely preventing a result, outcome or future state completely.

“Doped regions,” “semiconductor regions,” and similar terms describe regions of a semiconductor disposed in, on, above or over a substrate. Such regions can have an N-type conductivity or a P-type conductivity, and doping concentrations can vary. Such regions can refer to a plurality of regions, such as first doped regions, second doped regions, first semiconductor regions, second semiconductor regions, etc. The regions can be formed of a polycrystalline silicon on a substrate or as portions of the substrate itself.

“Thin dielectric layer,” “tunneling dielectric layer,” “dielectric layer,” “thin dielectric material” or intervening layer/material refers to a material on a semiconductor region, between a substrate and another semiconductor layer, or between doped or semiconductor regions on or in a substrate. In an embodiment, the thin dielectric layer can be a tunneling oxide or nitride layer of a thickness of approximately 2 nanometers or less. The thin dielectric layer can be referred to as a very thin dielectric layer, through which electrical conduction can be achieved. The conduction can be due to quantum tunneling and/or the presence of small regions of direct physical connection through thin spots in the dielectric layer. Exemplary materials include silicon oxide, silicon dioxide, silicon nitride, and other dielectric materials.

“Intervening layer” or “insulating layer” describes a layer that provides for electrical insulation, passivation, and inhibit light reflectivity. An intervening layer can be several layers, for example a stack of intervening layers. In some contexts, the insulating layer can be interchanged with a tunneling dielectric layer, while in others the insulating layer is a masking layer or an “antireflective coating layer” (ARC layer). Exemplary materials include silicon nitride, silicon oxynitride, silicon dioxide, aluminum oxide, amorphous silicon, polycrystalline silicon, molybdenum oxide, tungsten oxide, indium tin oxide, tin oxide, vanadium oxide, titanium oxide, silicon carbide and other materials. In an example, the intervening layer can include a material that can act as a moisture barrier. Also, for example, the insulating layer can be a passivation layer for a solar cell.

“Substrate” can refer to, but is not limited to, semiconductor substrates, such as silicon, and specifically such as single crystalline silicon substrates, multi-crystalline silicon substrates, wafers, silicon wafers and other semiconductor substrates used for solar cells. In an example, such substrates can be used in micro-electronic devices, photovoltaic cells or solar cells, diodes, photo-diodes, printed circuit boards, and other devices. These terms are used interchangeably herein.

“About” or “approximately”. As used herein, the terms “about” or “approximately” in reference to a recited numeric value, including for example, whole numbers, fractions, and/or percentages, generally indicates that the recited numeric value encompasses a range of numerical values (e.g., +/−5% to 10% of the recited value) that one of ordinary skill in the art would consider equivalent to the recited value (e.g., performing substantially the same function, acting in substantially the same way, and/or having substantially the same result).

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Subtractive metallization approaches for fabricating solar cells, and the resulting solar cells, are described herein. In the following description, numerous specific details are set forth, such as specific process flow operations, in order to provide a thorough understanding of embodiments of the present disclosure. It will be apparent to one skilled in the art that embodiments of the present disclosure can be practiced without these specific details. In other instances, well-known fabrication techniques, such as lithography and patterning techniques, are not described in detail in order to not unnecessarily obscure embodiments of the present disclosure. Furthermore, it is to be understood that the various embodiments shown in the figures are illustrative representations and are not necessarily drawn to scale.

Disclosed herein are solar cells. In one embodiment, a solar cell includes a semiconductor region in or above a substrate. The solar cell can include a metal foil or a metal foil portion disposed above the semiconductor region. In an embodiment, as used herein, the metal foil and metal foil portion can refer to the same structure and be used interchangeably. The metal foil portion can include an adhesive layer thereon. In an embodiment, the metal foil portion can include a top surface, a bottom surface, and a sidewall surface, the bottom surface having the adhesive layer thereon. The adhesive layer is above the semiconductor region and has an opening therein exposing a portion of the semiconductor region. A conductive material is on and electrically coupled to the portion of the semiconductor region exposed by the opening in the adhesive layer. In an embodiment, the conductive material is further on and electrically coupled to a sidewall surface of the metal foil portion. In one embodiment, the conductive material can be coupled to the bottom surface of the metal foil portion.

Also disclosed herein are methods of fabricating solar cells. In one embodiment, a method of fabricating a solar cell includes locating a metal foil above a semiconductor region in or above a substrate, the metal foil having a bottom surface with an adhesive layer thereon. An etch mask is formed above the metal foil, the etch mask having an opening exposing a portion of the metal foil. The exposed portion of the metal foil is etched to form a metal foil portion having an opening exposing a portion of the adhesive layer. The etch mask is removed. The exposed portion of the adhesive layer is removed to form a patterned adhesive layer having an opening exposing a portion of the semiconductor region. In one example, the exposed portion of the adhesive layer is removed to form a patterned adhesive layer having an opening exposing an underlying intervening layer disposed above the portion of the semiconductor region. In an embodiment, removing the exposed portion of the adhesive layer can include removing the exposed portion of the intervening layer. In an example, a laser can be used to form an opening in the adhesive layer and the intervening layer to expose the portion of the semiconductor region. In an embodiment, the intervening layer includes an opening in alignment with the opening in the adhesive layer, the opening in the intervening layer exposes the portion of the semiconductor region. A conductive material is formed in the opening of the metal foil portion and in the opening of the adhesive layer. The conductive material is on the exposed portion of the semiconductor region.

In one embodiment, a method of fabricating a solar cell includes locating a pre-patterned metal foil above a semiconductor region in or above a substrate, the pre-patterned metal foil having a bottom surface with an adhesive layer thereon, and the pre-patterned metal foil having an opening exposing a portion of the adhesive layer. An etch mask is formed above the pre-patterned metal foil, the etch mask covering a portion of the pre-patterned metal foil and covering the opening in the pre-patterned metal foil, and the etch mask exposing another portion of the pre-patterned metal foil. The exposed portion of the pre-patterned metal foil is etched to form a metal foil portion. The etch mask is removed. In an embodiment, an exposed portion of the adhesive layer can be removed to form a patterned adhesive layer having an opening exposing a portion of the semiconductor region. In one example, the exposed portion of the adhesive layer is removed to form a patterned adhesive layer having an opening exposing an underlying intervening layer disposed over the semiconductor region. In an embodiment, removing the exposed portion of the adhesive layer can include removing the exposed portion of the intervening layer. In an example, a laser can be used to form an opening in the adhesive layer and the intervening layer to expose the portion of the semiconductor region. In an embodiment, when the exposed portion of the pre-patterned metal foil is etched to form a metal foil portion, another exposed portion of the adhesive layer can remain or can be removed. In another embodiment, the pre-patterned metal foil can include a pre-patterned adhesive layer thereon, e.g., the pre-patterned adhesive layer disposed on a bottom surface of the pre-patterned metal foil. In the same embodiment where the pre-patterned metal foil can include a pre-patterned adhesive layer, both the pre-patterned metal foil and pre-patterned adhesive layer can include an opening which exposes the semiconductor region. In an example, the opening in the pre-patterned metal foil and the pre-patterned adhesive layer can be concentric. A conductive material is formed in the opening of the metal foil portion and in the opening of the adhesive layer. The conductive material is on the exposed portion of the semiconductor region.

In some embodiments, a conductive material can be placed on a metal foil. In an embodiment, the conductive material already in contact with the metal foil can be aligned and placed in an opening of an adhesive layer, the adhesive layer disposed over a substrate. In some embodiments, the adhesive layer can be pre-patterned to form the openings in the adhesive layer. In an embodiment, similar to the above, a laser process can be used to form the openings in the adhesive layer. In an embodiment, forming the openings in the adhesive layer can include forming openings in an intervening layer. In an embodiment, the intervening layer is disposed between the adhesive layer and semiconductor portions in or above the substrate. In an embodiment, the conductive material can be placed, instead, in the openings in the adhesive layer and the metal foil subsequently placed above the conductive material in the opening in the adhesive layer. Hence, in an embodiment, the metal foil need not include an opening and the conductive material can be in direct contact with a bottom surface of the metal foil and the semiconductor region in or above the substrate.

Thus, one or more embodiments described herein are directed to metallization techniques for fabricating solar cell contacts. According to embodiments, a metal foil, such as a copper foil, can be used to fabricate conductive contacts for an interdigitated back contact (IBC) solar cell architecture. In some embodiments, an aluminum foil can be used.

To provide context, due to high cost of silver paste, photovoltaic industries have put a lot of effort into reducing the amount of silver consumption per cell or replacing silver with other metals. Copper is an attractive material because of its lower cost and similar conductivity compared with silver. Currently, copper metallization involves many process operations, including barrier/seed coating, forming gas anneal (FGA), patterning, electroplating, resist stripping, and barrier/seed etching. Some of these operations can require either long process times or complicated equipment, or both, resulting in high cost of operation. A simpler, lower cost alternative is needed to reduce the manufacturing cost. More particularly, a significant fraction of the manufacturing cost of solar cells (especially interdigitated back contact (IBC) cells) is incurred during the metallization process. Metallization typically involves applying a metal seed layer, plating or bonding a thick metal layer to the metal seed layer, and then performing one or more process operations to pattern the metal seed layer and/or thick metal layers to form the desired pattern. By bonding a metal foil directly to the cell, one or more of the above operations can be eliminated.

It is to be appreciated that improvements in metallization methods for forming conductive contacts of solar cells are generally desirable. In contrast to some metallization methods, e.g., plating conductive contacts on a solar cell, according to embodiments described herein, a subtractive metallization process involves the use of copper foil as a contact material. A representative process sequence for the metallization process involves: (1) laminating a metal foil (such as a copper foil) to a silicon wafer following front-end processing, (2) printing an etch mask on the metal foil to define a finger pattern, (3) removing the unmasked metal foil by etching, (4) laser contact opening through a via in the metal foil, and (5) forming metal contacts with metal paste printing. Various examples are provided throughout.

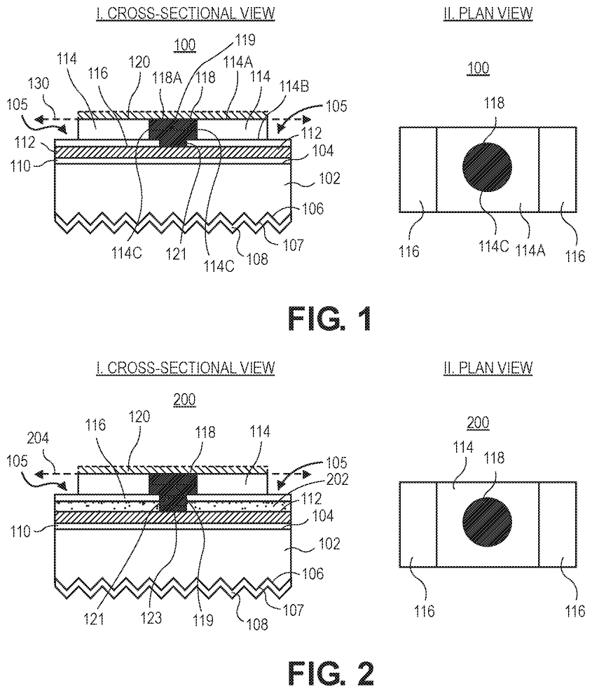

As an exemplary structure, FIG. 1 illustrates a cross-sectional view and corresponding plan view of a solar cell, in accordance with an embodiment of the present disclosure. In an example, the solar cell of FIG. 1 can include a foil-based metallization. The plan view is taken through axis 130 of the cross-sectional view.

Referring to FIG. 1, a solar cell 100 includes a substrate 102, such as a monocrystalline silicon substrate. The substrate 102 has a back side 104 and a front side 106, the front side 106 opposite the back side 104. In some embodiments, the front side 106 can be referred to as a front surface and the back side 104 can be referred to as a back surface. In an embodiment, the front side 106 can have a texturized surface 107. A texturized surface can be one which has a regular or an irregular shaped surface for scattering incoming light, decreasing the amount of light reflected off the light-receiving and/or exposed surfaces of the solar cell 100. An anti-reflective coating layer 108 can be conformal with the texturized surface 107, as is depicted. Although, as depicted, the structures shown are located on the back side 104, in an embodiment, the features described can instead be located on the front side 106 of the solar cell 100.

A semiconductor region 112 can be in or above the back side 104 of the substrate 102. In the example illustrated in FIG. 1, a semiconductor region 112 is a semiconductor layer above the back side 104 of the substrate 102. In one embodiment, the semiconductor layer is on a thin dielectric layer 110, as is depicted. In some embodiments, the semiconductor region can be disposed in the substrate 102. In an example, the semiconductor layer can include a P-type or N-type doped region.

Referring again to FIG. 1, the solar cell 100 includes a metal foil portion 114. The metal foil portion 114 can include an opening 119. The metal foil portion can have a top surface 114A, a bottom surface 114B, and a sidewall surface 114C within the opening 119 of the metal foil 114. The bottom surface 114B can include an adhesive layer 116 thereon. The adhesive layer 116 can be above the semiconductor region 112 and can include an opening 121 therein exposing a portion of the semiconductor region 112. A conductive material 118 can be disposed on and electrically coupled to the portion of the semiconductor region 112 exposed by the opening 121 in the adhesive layer 116. The conductive material 118 can further be on and electrically coupled to the sidewall surface 114C of the metal foil portion 114.

In an embodiment, the conductive material 118 can be referred to as a conductive adhesive in that it can adhere to the semiconductor region 112. In general, the conductive material 118 can act to electrically conduct between the semiconductor region 112 and the metal foil 114. In an embodiment, the conductive material 118 can be a paste such as, but not limited to an aluminum paste, a copper paste, or a silver paste.

In an embodiment, the conductive material 118 has a top surface 118A substantially co-planar with the top surface 114A of the metal foil portion 114, as is depicted. It is to be appreciated that an arrangement having the top surface 114A of the conductive material 118 co-planar with the metal foil portion 114 may be preferred but is not required if an associated back sheet is compliant and does not cause a wafer/substrate to crack in a PV module. In an embodiment, the sidewall surface 114C of the metal foil portion 114 can completely laterally surround the conductive material 118, as is also depicted.

The adhesive layer 116 can electrically isolate the bottom surface 114B of the metal foil portion 114 from the semiconductor region 112. In an embodiment, the adhesive layer 116 is directly on the semiconductor region 112, as is depicted. In one embodiment, adhesive layer 116 is a Dupont Pyralux LF sheet adhesive.

In an embodiment, the metal foil portion 114 has a thickness approximately in the range of 5-100 microns. In an embodiment, the metal foil portion 114 is a copper (Cu) foil portion. In an example, the metal foil portion 114 can include copper foil and/or a copper alloy foil. In another embodiment, the metal foil portion 114 is an aluminum (Al) foil. In one embodiment, the Al foil is an aluminum alloy foil including aluminum and second element such as, but not limited to, copper, manganese, silicon, magnesium, zinc, tin, lithium, or combinations thereof. In one embodiment, the Al foil is a temper grade foil such as, but not limited to, F-grade (as fabricated), O-grade (full soft), H-grade (strain hardened) or T-grade (heat treated). In one embodiment, the aluminum foil is an anodized aluminum foil. In another embodiment, the aluminum foil is not anodized. In an example, portions of the metal foil can be anodized where other portions of the foil are not anodized.

In an embodiment, the conductive material 118 is a conductive paste or a conductive seed material. In an embodiment, the conductive material 118 is or includes a metal selected from the group consisting of copper, aluminum, silver and tin. In an embodiment, a portion of the conductive material 118 on the sidewall surface 114C of the metal foil portion 114 has a width approximately greater than a portion of the conductive material 118 in the opening 121 in the adhesive layer 116, as is depicted. In an embodiment, the portion of the conductive material 118 on the sidewall surface 114C of the metal foil portion 114 has a width approximately equal to the portion of the conductive material 118 in the opening 121 in the adhesive layer 116. In some embodiments, the portion of the conductive material 118 on the sidewall surface 114C of the metal foil portion 114 has a width approximately less than the portion of the conductive material 118 in the opening 121 in the adhesive layer 116.

In an embodiment, solar cell 100 further includes an optional conductive layer 120 over the top surface 114A of the metal foil portion 114. The conductive layer 120 is directly on and electrically coupled to the conductive material 118. In an embodiment, the conductive layer 120 is further directly on the top surface 114A of the metal foil portion 114, as is depicted. In an embodiment, the conductive layer 120 is or includes a solder paste. The solder paste can be deposited on the metal foil 114 directly by stencil printing, 3D printing or other dispensing methods. In an embodiment, the conductive layer 120 can be deposited over some portions of the metal foil 114, where other portions of the metal foil 114 can be exposed. In an example, the conductive layer 120 can be located at contact pad portions of the solar cell 100, where other portions such as contact fingers of the solar cell 100, do not include the conductive layer 120.

In an embodiment, the semiconductor region 112 is a polycrystalline silicon layer on a thin dielectric layer 110 on the substrate. In one embodiment, the polycrystalline silicon layer is N-type (e.g., formed using phosphorus or arsenic impurity atoms). In another embodiment, the polycrystalline silicon layer is P-type boron (e.g., formed using boron impurity atoms). In some embodiments, the polycrystalline silicon layer is a pre-doped polycrystalline silicon layer. In one embodiment, the thin dielectric layer 110 is a thin oxide layer such as a tunnel dielectric layer (e.g., tunnel oxide, silicon oxynitride, silicon oxide). In an embodiment, the thin dielectric layer 110 can have a thickness of approximately 2 nanometers or less. In other embodiments, semiconductor region 112 is instead a doped region of the substrate 102.

It is to be understood that although examples of the structures shown herein can be located on a back side of a solar cell 100. In an embodiment, the structures described can also be located or positioned on a front side of a solar cell. For example, the metal foil portion 114, adhesive layer 116, and conductive material 118 can be located on a front side of the solar cell 100 instead of a back side of the solar cell 100.

Referring again to FIG. 1, as shown, portions of the adhesive layer at 105 can be exposed. In an embodiment, the adhesive layer 116 can extend past the metal foil portion 114, covering portions 105. In some embodiments, these portions can instead be removed (e.g., via an etching process or a laser ablation process) and the semiconductor region 112 or substrate 102 can instead be exposed at 105.

As an exemplary structure, FIG. 2 illustrates a cross-sectional view and corresponding plan view of another solar cell, in accordance with another embodiment of the present disclosure. The plan view is taken through axis 204 of the cross-sectional view of FIG. 2. Reference numbers in FIG. 2 common to those of FIG. 1 are the same or similar to those described in association with FIG. 1.

Referring to FIG. 2, a solar cell 200 includes an intervening layer 202 between the adhesive layer 116 and the semiconductor region 112. In one embodiment, the intervening layer 202 can be another insulating layer. In an embodiment, the intervening layer 202 can include an anti-reflective coating (ARC) layer. In an example, the intervening layer 202 can include a material such as silicon oxide, silicon nitride or silicon oxynitride. A conductive material 118 can be disposed on and electrically coupled to the portion of the semiconductor region 112 exposed by the opening 121 in the adhesive layer 116 and the intervening layer 202, where the conductive material 118 can further be on and electrically coupled to the sidewall surface 114C of the metal foil portion 114. The conductive material 118 extends further through an opening 123 in the intervening layer 202 to contact the semiconductor region 112. In an example, an opening in the adhesive layer 121 exposes an opening 123 in the intervening layer 202, allowing the conductive material 118 to extend through both the adhesive layer 116 and the intervening layer 202 to contact the semiconductor region 112.

Referring again to FIG. 2, in an embodiment, a portion of the conductive material 118 in an opening 119 of the metal foil portion 114 has a width approximately greater than a portion of the conductive material 118 in the opening 121 of the adhesive layer 116, as is depicted. Alternatively, in an embodiment, the portion of the conductive material 118 in the opening 119 of the metal foil portion 114 has a width approximately equal to the portion of the conductive material 118 in the opening 121 of the adhesive layer. In some embodiments, the portion of the conductive material 118 in the opening 119 of the metal foil portion 114 has a width approximately less than the portion of the conductive material 118 in the opening 123 in the intervening layer 202. In an embodiment, the portion of the conductive material 118 in the opening 123 of the adhesive layer 116 can have a width approximately equal to the portion of the conductive material 118 in the opening 123 of the intervening layer 202. In an embodiment, the portion of the conductive material 118 in the opening 121 of the adhesive layer 116 can have a width approximately greater than the portion of the conductive material 118 in the opening 123 of the intervening layer 202. Alternatively, in an embodiment, the portion of the conductive material 118 in the opening 121 of the adhesive layer 116 can have a width approximately less than the portion of the conductive material 118 in the opening 123 of the intervening layer 202.

Referring again to FIG. 2, as shown, portions of the adhesive layer at 105 can be exposed. In an embodiment, the adhesive layer 116 can extend past the conductive foil portion 114, covering portions 105. In some embodiments, these portions can instead be removed (e.g., via an etching process or a laser ablation process) and the intervening layer 202, semiconductor region 112 and/or substrate 102 can instead be exposed at 105.

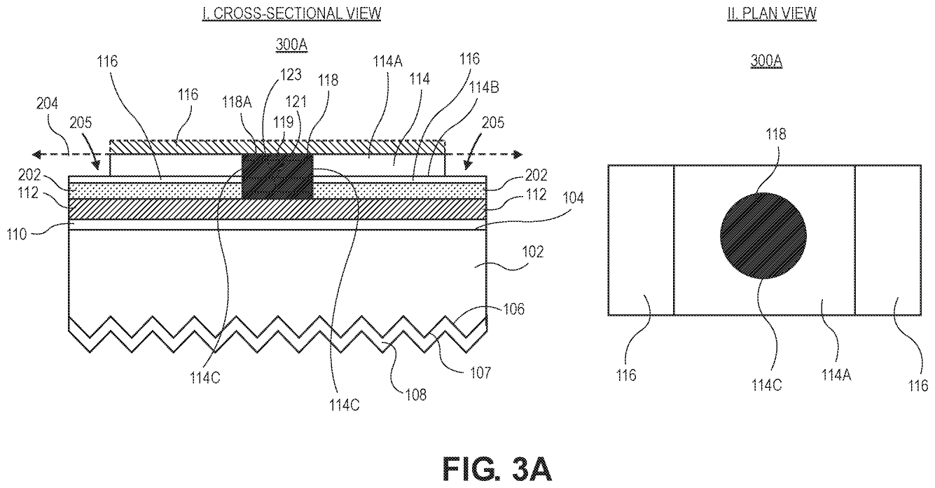

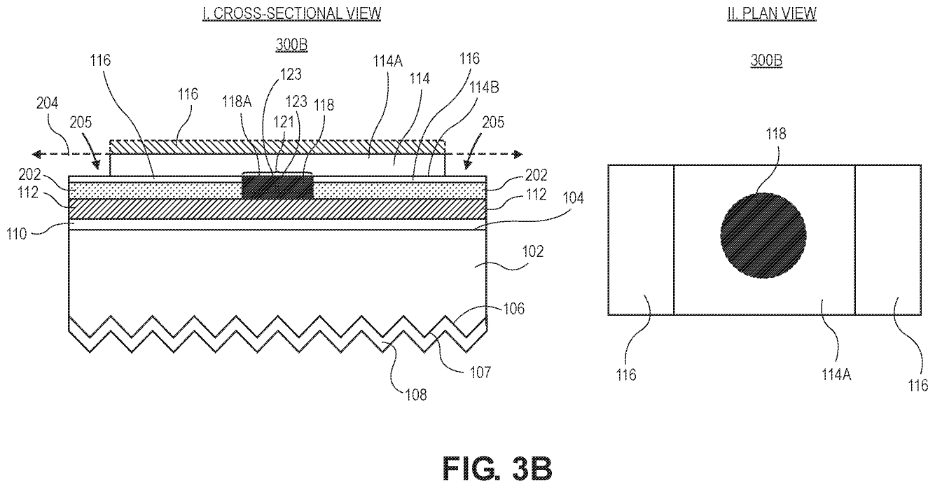

As an exemplary structure, FIG. 3A illustrates a cross-sectional view and corresponding plan view of another solar cell, in accordance with another embodiment of the present disclosure. The plan view is taken through axis 204 of the cross-sectional view of FIG. 3A. Reference numbers in FIG. 3A common to those of FIGS. 1, and 2 are the same or similar to those described in association with FIGS. 1, and 2.

Referring to FIG. 3A, a solar cell 300A, includes an intervening layer 202 between the adhesive layer 116 and the semiconductor region 112, where the width of an opening 121 in the adhesive layer 116 is approximately equal to the width of an opening 123 in the intervening layer 202. Referring to FIG. 3A, in an embodiment, the portion of the conductive material 118 in the opening 119 of the metal foil portion 114 has a width approximately equal to the portion of the conductive material 118 in the opening 121 of the adhesive layer 116, as depicted. In an embodiment, the portion of the conductive material 118 in the opening 121 of the adhesive layer 116 can have a width approximately equal to the portion of the conductive material 118 in the opening 123 of the intervening layer 202, as also shown. In an embodiment, as shown, the conductive material 118 has a width approximately equal to the portion of the conductive material 118 in the opening 119 of the metal foil portion 114, the opening 121 of the adhesive layer 116 and the opening 123 of the intervening layer 202. In an embodiment, the adhesive layer 116 can extend past the conductive foil portion 114, covering portions 205 of the intervening layer 202 and/or semiconductor region 112 not covered by the foil portions 114. In an embodiment, the adhesive layer 116 and intervening layer 202 not covered by the foil portions 114 at 205 can instead be located directly below the metal foil portions 114, where portions of the semiconductor layer 112 can be exposed.

As an exemplary structure, FIG. 3B illustrates a cross-sectional view and corresponding plan view of another solar cell, in accordance with another embodiment of the present disclosure. The plan view is taken through axis 204 of the cross-sectional view of FIG. 3B. Reference numbers in FIG. 3B common to those of FIGS. 1, 2 and 3A are the same or similar to those described in association with FIGS. 1, 2, and 3A.

Referring to FIG. 3B, a solar cell 300B includes a metal foil 114 disposed above a conductive material 118. In an embodiment, in contrast to the embodiments proposed above, the metal foil 114 can be disposed directly over the conductive material 118. Also, in an embodiment, FIG. 3B includes a metal foil 114 without an opening, e.g., a portion of the metal foil 114 is in contact with and disposed directly above the conductive material 118. In an example, the metal foil 114 is continuous above an adhesive layer 116 and the conductive material 118. In an embodiment, a bottom surface 114B of the metal foil 114 can be above the openings 121 of the adhesive layer 116 and in contact with a top surface 118A of the conductive material 118. In an embodiment, a portion of the conductive material 118 in an opening 121 of the adhesive layer 116 has a width approximately greater than a portion of the conductive material 118 in an opening 123 of the intervening layer 202. In some embodiments, the portion of the conductive material 118 in the opening 121 of the adhesive layer 116 has a width approximately equal to the portion of the conductive material 118 in the opening 123 of the intervening layer 202, as is depicted. In some embodiments, the portion of the conductive material 118 in the opening 121 of the adhesive layer 116 has a width approximately less than the portion of the conductive material 118 in the opening 123 of the intervening layer 202. In an embodiment, the adhesive layer 116 can extend past the conductive foil portion 114, covering portions 205 of the intervening layer 202 and/or semiconductor 112 not covered by the foil portions 114. In an embodiment, the adhesive layer 116 and the intervening layer 202 not covered by the foil portions 114 at 205 can instead be located directly below the metal foil portions 114, where portions of the semiconductor region 112 can be exposed.

Referring to the part II. Plan View of FIG. 3B, the top surface 114A of the metal foil 114 is shown, where a conductive material 118 is disposed underneath metal foil 114. In the example shown, the metal foil 114 can be disposed over the conductive material 118, where the dotted line in 118 depicts the conductive material located underneath and/or below the metal foil 114. In an example, the conductive material 118 should not be visible from the plan view.

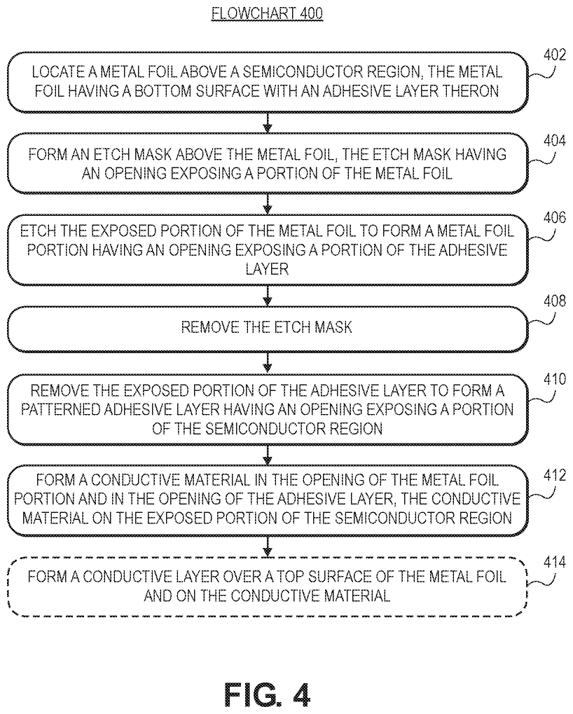

FIG. 4 is a flowchart 400 including various operations in a method of fabricating a solar cell, in accordance with an embodiment of the present disclosure.

Referring to flowchart 400 of FIG. 4, at operation 402, a method of fabricating a solar cell includes locating a metal foil above a semiconductor region in or above a substrate. The metal foil has a bottom surface with an adhesive layer thereon. At operation 404, an etch mask is formed above the metal foil. The etch mask has an opening exposing a portion of the metal foil. At operation 406, the exposed portion of the metal foil is etched to form a metal foil portion having an opening exposing a portion of the adhesive layer. At operation 408, the etch mask is removed. At operation 410, a method of fabricating a solar cell includes removing the exposed portion of the adhesive layer to form a patterned adhesive layer having an opening exposing a portion of the semiconductor region. In one embodiment, removing the exposed portion of the adhesive layer involves using a laser ablation process. In one example, the exposed portion of the adhesive layer is removed to form a patterned adhesive layer having an opening exposing an underlying intervening layer disposed above the portion of the semiconductor region. In an embodiment, removing the exposed portion of the adhesive layer can include removing the exposed portion of the intervening layer. In an example, a laser can be used to form an opening in the adhesive layer and the intervening layer to expose the portion of the semiconductor region. At operation 412, a conductive material is formed in the opening of the metal foil portion and in the opening of the adhesive layer. In an embodiment, the conductive material is formed on the exposed portion of the semiconductor region. At operation 414, a conductive layer is optionally formed over a top surface of the metal foil portion and on the conductive material.

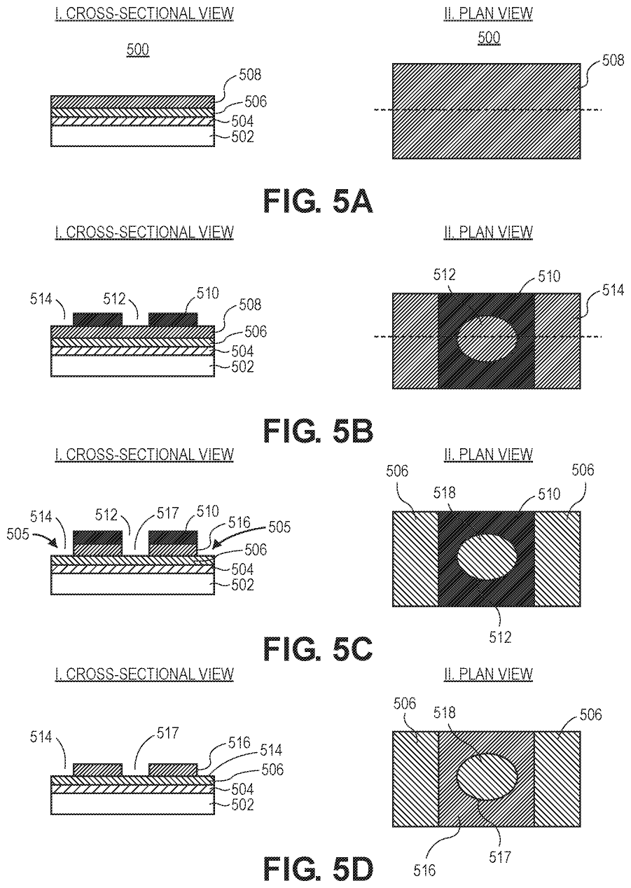

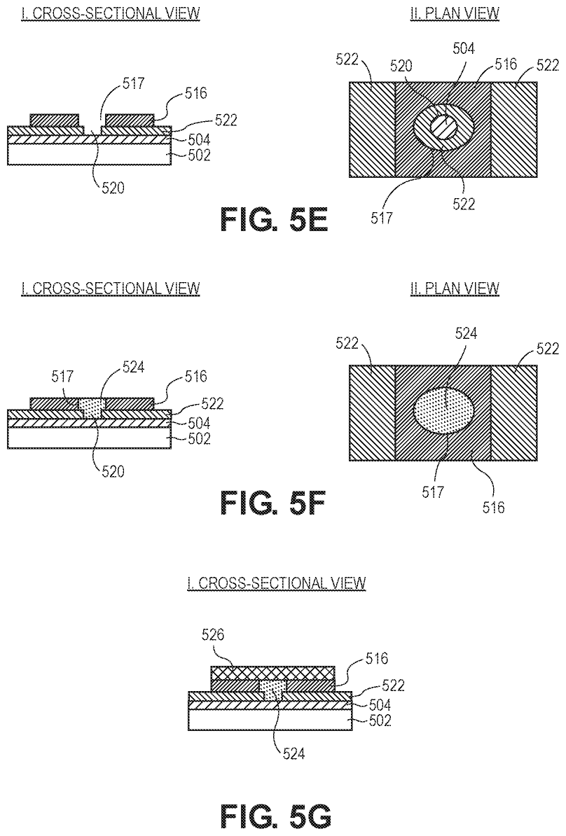

As an exemplary process scheme including a combination of operations described above in association with FIG. 4 and FIGS. 5A-5G illustrate cross-sectional views and corresponding plan views representing various operations in a method of fabricating, in accordance with an embodiment of the present disclosure.

Referring to FIG. 5A, a starting structure 500 in a method of fabricating a solar cell is formed by locating a metal foil 508 above a semiconductor region 504 in or above a substrate 502. The metal foil 508 has a bottom surface with an adhesive layer 506 thereon. In an embodiment, referring to FIGS. 2, 3A and 3B, an intervening layer can be formed above the semiconductor region 504, where the intervening layer can be disposed between the adhesive layer 506 and the semiconductor region 504. It is to be understood that the structure 500 can include the intervening layer and, in some embodiments, as shown the structure 500 does not include the intervening layer.

Referring to FIG. 5B, an etch mask 510 is formed above the metal foil 508. The etch mask 510 has an opening 512 exposing a portion of the metal foil 508. Other portions of metal foil 508 can be exposed by etch mask 510 at locations 514.

In some embodiments, the opening below 512 in the metal foil 516 need not be formed. In an example, referring to FIG. 3B, a conductive material can be located below the metal foil at the position of 512. Referring to the same embodiment, in this case the adhesive layer can be pre-patterned and the conductive material located in an opening in the adhesive layer. In the same embodiment where conductive material can be located below the metal foil without an opening, in some embodiments, the conductive material is disposed first on the metal foil and the pre-patterned adhesive layer located on the metal foil, or vice versa.

Referring to FIG. 5C, the exposed portion of the metal foil 508 is etched to form a metal foil portion 516 having an opening 517 exposing a portion of the adhesive layer 506. Additionally, portions of the adhesive layer 506 at locations 514 can be exposed. In some embodiments, portions of the adhesive layer 506 can be removed and expose the underlying semiconductor region 504 at 514.

Referring to FIG. 5D, the etch mask 510 is removed. In an embodiment, the removal process can include a mask removal process. In an example, a wet process and/or an ink strip process can be used to remove the etch mask 510.

Referring to FIG. 5E, the exposed portion of the adhesive layer 506 is removed to form a patterned adhesive layer 522 having an opening 520 exposing a portion of the semiconductor region 504. In one embodiment, removing the exposed portion of the adhesive layer 506 involves using a laser ablation process. In an embodiment, removing the exposed portion of the adhesive layer can include removing the exposed portion of an intervening layer. In an example, a laser can be used to form an opening in the adhesive layer and the intervening layer to expose the portion of the semiconductor region.

Referring to FIG. 5F, a conductive material 524 is formed in the opening 517 of the metal foil portion 516 and in the opening 520 of the adhesive layer 522. The conductive material 524 is on the exposed portion of the semiconductor region 504. In an embodiment, the conductive material physically and electrically connects the metal foil 516 to the semiconductor region 504, where the adhesive layer 522 electrically isolates a bottom portion of the metal foil 516 from the semiconductor region 504.

Referring to FIG. 5G, an optional conductive layer 526 can be formed over a top surface of the metal foil portion 516 and on the conductive material 524. In an embodiment, the conductive layer 526 can be deposited over some portions of the metal foil 516, where other portions of the metal foil 516 can be exposed. In an example, the conductive layer 526 can be located at contact pad portions of the solar cell 500, where other portions (e.g., such as contact fingers of the solar cell) do not include the conductive layer 526.

Referring again to FIGS. 5E, 5F and 5G, in another embodiment, the conductive material 524 can be pre-formed and located below the metal foil at the position of 517, where the metal foil 522 does not include an opening (e.g., is continuous). Referring to the same embodiment, in this case the adhesive layer can be pre-patterned, and the conductive material 524 located in an opening in the adhesive layer 522. Thus, a structure as shown in FIG. 3B can be formed.

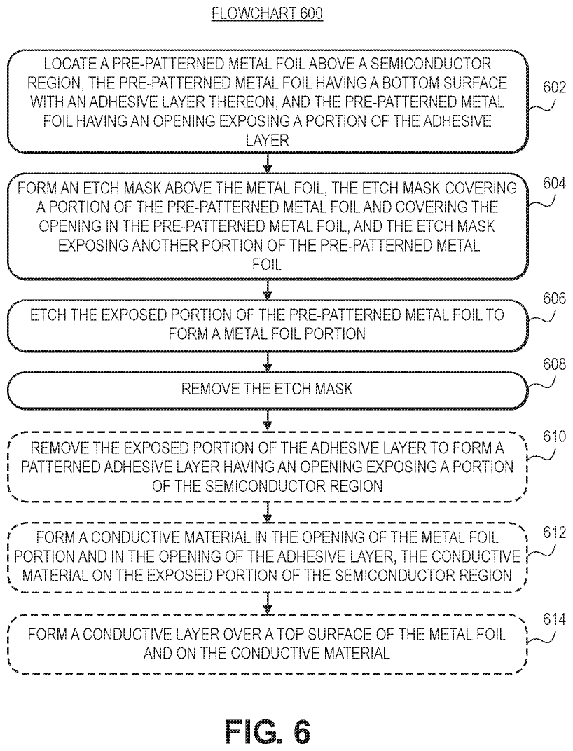

FIG. 6 is a flowchart including various operations in another method of fabricating a solar cell, in accordance with another embodiment of the present disclosure.

Referring to flowchart 600 of FIG. 6, at operation 602, a method of fabricating a solar cell includes locating a pre-patterned metal foil above a semiconductor region in or above a substrate. The pre-patterned metal foil has a bottom surface with an adhesive layer thereon, and the pre-patterned metal foil has an opening exposing a portion of the adhesive layer. In another embodiment, the pre-patterned metal foil can include a pre-patterned adhesive layer disposed on the bottom surface. In the same embodiment where pre-patterned metal foil can include the pre-patterned adhesive layer, a metal foil including an adhesive layer can be provided and can be patterned to form the pre-patterned metal foil and the pre-patterned adhesive layer. In an example, patterning the metal foil including an adhesive layer can be performed prior to operation 602. In an example, a mechanical drilling process can be used to form the pre-patterned metal foil and the pre-patterned adhesive layer. At operation 604, an etch mask is formed above the metal foil. The etch mask covers a portion of the pre-patterned metal foil and covers the opening in the pre-patterned metal foil. The etch mask exposes another portion of the pre-patterned metal foil. In some embodiments, the etch mask exposes the opening of the pre-patterned metal foil and the adhesive layer in the opening. At operation 606, the exposed portion of the pre-patterned metal foil is etched to form a metal foil portion. At operation 608, the etch mask is removed. At operation 610, a method of fabricating a solar cell includes removing the exposed portion of the adhesive layer to form a patterned adhesive layer having an opening exposing a portion of the semiconductor region. In an embodiment, removing the exposed portion of the adhesive layer can include removing the exposed portion of an intervening layer. In an example, a laser can be used to form an opening in the adhesive layer and the intervening layer to expose the portion of the semiconductor region. In an embodiment, where the adhesive layer is already patterned, a laser ablation process can remove a portion of an intervening layer exposed by opening in the adhesive layer and the metal foil. In an example, a wet process such as an ink strip process can be used to remove the etch mask at operation 608. In some embodiments, the operations 604, 606, 608, and 610 are optional, e.g., where the pre-patterned metal foil includes a pre-patterned adhesive layer. At operation 612, a conductive material is formed in the opening of the metal foil portion and in the opening of the adhesive layer. In an embodiment, the conductive material is formed on the exposed portion of the semiconductor region. At operation 614, a conductive layer is optionally formed over a top surface of the metal foil portion and on the conductive material.

As an exemplary process scheme including a combination of operations described above in association with FIGS. 6 and 4, FIGS. 7A-7E illustrate cross-sectional views and corresponding plan views representing various operations in another method of fabricating a solar cell having foil-based metallization, in accordance with another embodiment of the present disclosure.

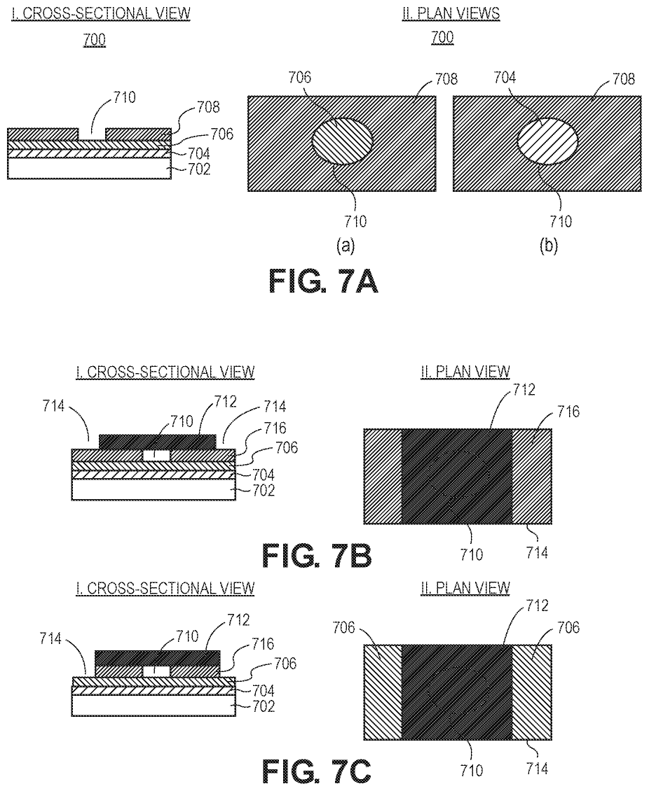

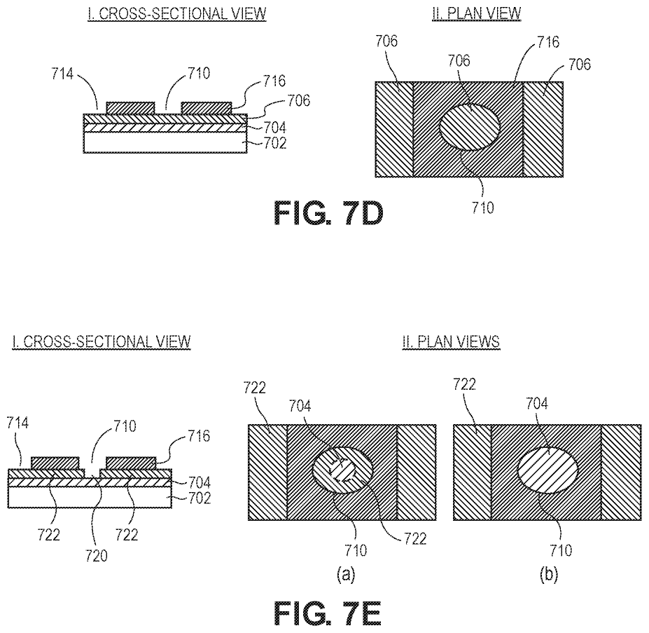

Referring to the cross-sectional view and the plan view (a) of FIG. 7A, a starting structure 700 in a method of fabricating a solar cell is formed by locating a pre-patterned metal foil 708 above a semiconductor region 704 in or above a substrate 702. The pre-patterned metal foil 708 has a bottom surface with an adhesive layer 706 thereon. The pre-patterned metal foil 708 also has an opening 710 exposing a portion of the adhesive layer 706. Referring to the plan view (b) of FIG. 7A, in an alternative embodiment, the adhesive layer 706 is etched through opening 710. In an embodiment, the adhesive layer 706 is already also pre-patterned, e.g., the exposing the semiconductor region 704 as shown in the plan view (b). In an example, forming the pre-patterned metal foil and the pre-patterned adhesive layer can include forming an opening in a metal foil and an adhesive layer, where the adhesive layer is on a bottom surface of the metal foil. In the same example, a mechanical drilling process can be used to form the opening in the metal foil and the adhesive layer. In an example, a mechanical drilling process can be used to form the pre-patterned metal foil and the pre-patterned adhesive layer from a metal foil and an adhesive layer, the adhesive layer on a back surface of the metal foil.

Referring to FIG. 7B, an etch mask 712 is formed above the pre-patterned metal foil 708. The etch mask 712 covers a portion of the pre-patterned metal foil 708 and covers the opening 710 in the pre-patterned metal foil 708. The etch mask 712 exposes another portion of the pre-patterned metal foil 708 at location 714. In an embodiment, the etch mask 712 can fill in the opening 710. In an example, the etch mask 712 can be located in the opening 710, above and directly in contact with the exposed adhesive layer 706.

Referring to FIG. 7C, the exposed portion of the pre-patterned metal foil 708 at location 714 is etched to form a metal foil portion 716. Additionally, portions of the adhesive layer 706 at locations 714 can be exposed. In some embodiments, portions of the adhesive layer 706 can be removed and expose the underlying semiconductor region 704 at 714.

Referring to FIG. 7D, the etch mask 712 is removed. In an embodiment, the removal process can include a mask removal process. In an example, a wet process and/or an ink strip process can be used to remove the mask 712.

Referring to the cross-sectional view and the plan view (a) of FIG. 7E, the exposed portion of the adhesive layer 706 is removed to form a patterned adhesive layer 722 having an opening 720 exposing a portion of the semiconductor region 704. In one embodiment, removing the exposed portion of the adhesive layer 706 involves using a laser ablation process. In an embodiment, removing the exposed portion of the adhesive layer 722 can include removing the exposed portion of an intervening layer. In an example, a laser can be used to form an opening in the adhesive layer 722 and the intervening layer to expose the portion of the semiconductor region 704. In an embodiment, where the adhesive layer 722 is already patterned, a laser ablation process can remove a portion of an intervening layer exposed by the opening in the adhesive layer 722 and the metal foil 716. The resulting structure illustrated in cross-sectional view and the plan view (a) of FIG. 7E effectively matches the structure described in association with FIG. 5E. Operations described in association with FIGS. 5F and 5G can be performed starting with the structure of illustrated in cross-sectional view and the plan view (a) of FIG. 7E.

In an alternative embodiment, referring to the plan view (b) of FIG. 7E, the structure shown is the result of processing the structure of plan view (b) of FIG. 7A through the processes described in association with FIGS. 7B-7D. The structure shown in the plan view (b) of FIG. 7E can have a conductive material formed in the opening 710 therein, along with further processing as described above. For comparison, the plan view (a) can include remaining adhesive layer 722 portions at 710 of the I. cross-sectional view of FIG. 7E. While in the plan view (b), the semiconductor region 704 is fully exposed, e.g., the opening of the metal foil 716 and of the adhesive layer 722 at 710 are approximately equal.

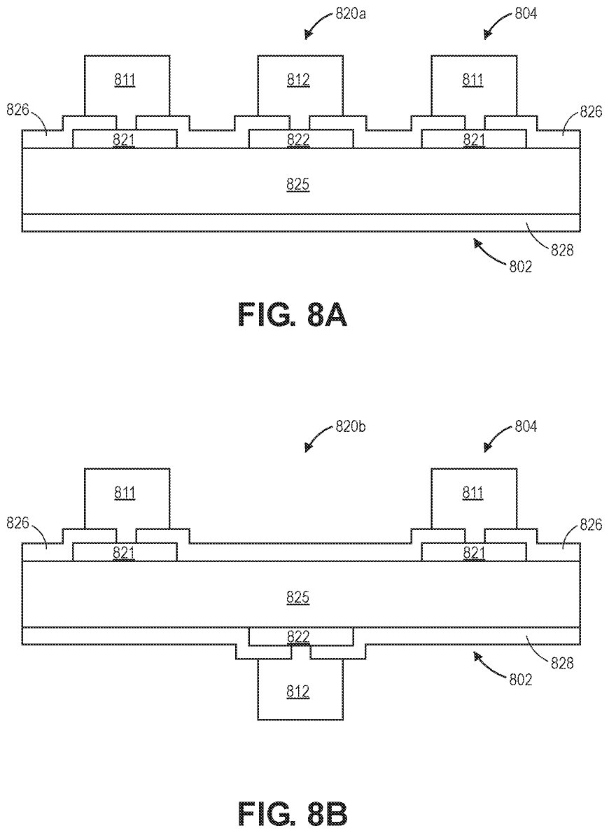

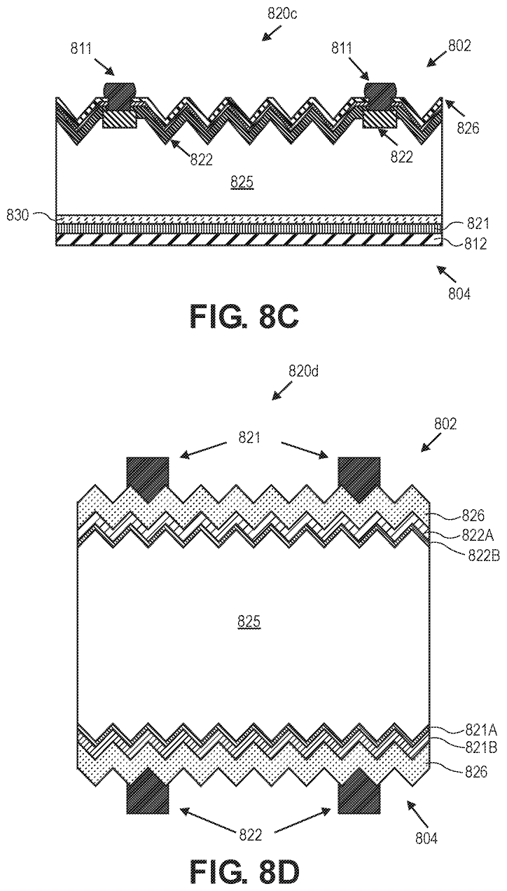

FIGS. 8A-8D illustrate example semiconductor substrates fabricated using methods, approaches or equipment described herein, according to some embodiments. In an embodiment, the semiconductor substrates are solar cells 820a, 820b, 820c, 820d. In an embodiment, the solar cells 820a, 820b, 820c, 820d can include a silicon substrate 825. In some embodiments, the silicon substrate 825 can be cleaned, polished, planarized and/or thinned or otherwise processed. In an embodiment, the semiconductor substrate 825 can be single-crystalline or a multi-crystalline silicon substrate. In an embodiment, the silicon substrate 825 can be an N-type or a P-type silicon substrate. In an example, the semiconductor substrate can be a monocrystalline silicon substrate, such as a bulk single crystalline N-type doped semiconductor substrate. In an embodiment, the solar cells 820a, 820b, 820c, 820d can have a front side 802 and a back side 804, where the front side 802 is opposite the back side 804. In one embodiment, the front side 802 can be referred to as a light receiving surface 802 and the back side 804 can be referred to as a back surface 804. In an embodiment, the solar cells 820a, 820b, 820c, 820d can include a first doped region 821 and a second doped region 822. In an embodiment, the first doped region can be a P-type doped region (e.g., doped with boron) and the second doped region can be an N-type doped region (e.g., doped with phosphorus). In an embodiment, the solar cells 820a, 820b, 820c, 820d can include an anti-reflective coating (ARC) 828 on the front side 802 of the solar cells. In some embodiments, the solar cells 820a, 820b, 820c, 820d can include an anti-reflective coating 826 on the back side 804, e.g., a back anti-reflective coating (BARC) layer.

Referring to FIG. 8A, an exemplary back-contact solar cell fabricated using methods, approaches or equipment described herein, according to some embodiments. The back-contact solar cell 820a can include the first and second doped regions 821, 822 disposed on a back side 804 of a solar cell 820a. In an embodiment, conductive metal foil portions 811, 812 can be bonded to the first and second doped regions 821, 822 on the back side 804. In an embodiment, the first and/or second doped regions 821, 822 can include polysilicon regions. In an embodiment, a thin dielectric layer (e.g., thin oxide layer, tunnel oxide layer) can be disposed between the first and second doped regions 821, 822 and the substrate 825. In an embodiment, the first and second doped regions 821, 822 can, instead, be located in the substrate 825. The first and second doped regions 821, 822 can have separation regions formed there between. In an example, the first and second doped regions 821, 822 have trenches formed there between, the trenches extending partially into the substrate. The trenches can be replaced with intrinsic or lightly doped semiconductor regions. In one example, first and second doped regions 821, 822 can be separated by a lightly doped a region 879 disposed between the first and second doped regions 821, 822, e.g., where the lightly doped regions can have a doping concentration substantially less than the first and second doped regions 821, 822. In one example, the portions 821, 822 can be part of a continuous semiconductor layer where a lightly doped region can separate the first and second doped regions 821, 822 from one another. In an embodiment,

With Reference to FIG. 8B, an example front-contact solar cell fabricated using methods, approaches or equipment described herein, according to some embodiments. The front-contact solar cell 820b can include the first doped regions 821 disposed on the back side 804 of the solar cell 820b. In an example, the second doped region 822 can be disposed on the front side 802 of the solar cell 820b. Although one example of a second doped region 822 is shown, one or more, of the second doped region 822 can be used. In an embodiment, conductive metal foil portions 811, 812 can be bonded to the first and second doped regions 821, 822 on the front and back sides 804 of the solar cell 820b. The second doped region 822 can offset from the first doped regions 821, as shown. The second doped region 822 can be aligned, e.g., vertically aligned with, the first doped regions 821. In an embodiment, the portions 821 can be part of a continuous semiconductor layer disposed over the back side 804 of the substrate 825 of FIG. 8B. In an embodiment, the portions 822 can be part of a continuous semiconductor layer disposed over the front side 802 of the substrate 825 of FIG. 8B. In an embodiment, a thin dielectric layer (e.g., thin oxide layer, tunnel oxide layer) can be disposed between the first and second doped regions 821, 822 and the substrate 825. In some embodiments, the first doped region and/or second doped region can be located in the substrate 825.

FIG. 8C illustrates an example front-contact solar cell fabricated using methods, approaches described herein, according to some embodiments. The front-contact solar cell 820c can include the first doped regions 821 disposed on the back side 804 of the solar cell 820c. Conductive contact structures 811, 812 can be formed via metal foil bonding techniques on the front and back sides 802, 804 of the solar cell 820c, respectively, where the conductive contact structures 811, 812 include subtractively formed metal foil portions on the first and second doped regions 821, 822. The first and second doped regions 821, 822 can include an amorphous silicon region. The solar cell 820d can include an intervening layer (e.g., an anti-reflective layer coating ARC) 826 on the front side 802 of the solar cell 820c. The solar cells 820c can include a back intervening layer (e.g., a back anti-reflective coating BARC) 826 on the back side 804 of the solar cell 820c. A thin oxide layer 830 can be disposed between the first doped region 821 and the substrate 825.

FIG. 8D illustrates another exemplary front-contact solar cell fabricated using methods, approaches or equipment described herein, according to some embodiments. The solar cell 820d can include the first doped regions 821A, 821B disposed on the back side 804 of the solar cell 820d. In an example, the second doped region 822A, 822B can be disposed on the front side 802 of the solar cell 820d. In an embodiment, conductive contact structures 811, 812 can be formed via a metal foil bonding and patterning technique on the front 802 and back sides 804 of the solar cell 820d, respectively, where the conductive contact structures 811, 812 include subtractively formed metal foil portions on the first and second doped regions 821A, 821B, 822A, 822B. The first doped regions 821A, 821B can include a doped polysilicon region. The solar cell 820d can include an intervening layer (e.g., an anti-reflective coating ARC) 826 on the front side 802 of the solar cell 820d. The solar cells 820d can include a back intervening layer (e.g., a back anti-reflective coating BARC) 826 on the back side 804 of the solar cell 820d.

Referring to FIGS. 8A-8D, in one embodiment, methods described herein can be applied to both a front-contact and/or a back-contact solar cell. In an example, conductive metal foil portions 810 can be aligned and bonded to doped regions 821, 822 on either of or both of a front side 802 and a back side 804 of a solar cell. In one example, the conductive metal foil portions 810 can be bonded to a single side, e.g., a back side 804 or a front side 802. In an embodiment, according to examples described above, the conductive contact structures 811, 812 can include a metal foil portion having a conductive material in an opening therein, where the conductive material is on and electrically coupled to the sidewall surface of the metal foil portion.

Although certain materials are described specifically with reference to above described embodiments, some materials can be readily substituted with others with such embodiments remaining within the spirit and scope of embodiments of the present disclosure. For example, in an embodiment, a different material substrate, such as a group III-V material substrate, can be used instead of a silicon substrate. Additionally, although reference is made significantly to back contact solar cell arrangements, it is to be appreciated that approaches described herein can have application to front contact solar cells as well. In other embodiments, the above described approaches can be applicable to manufacturing of other than solar cells. For example, manufacturing of light emitting diode (LEDs) can benefit from approaches described herein. Furthermore, it is to be appreciated that, where N+ and P+ type doping is described specifically, other embodiments contemplated include the opposite conductivity type, e.g., P+ and N+ type doping, respectively.

Thus, metallization approaches for fabricating solar cells, and the resulting solar cells, have been disclosed. The above structures and techniques can be readily applied and used in solar cell products such as solar cell strings, photovoltaic (PV) laminates and photovoltaic (PV) modules.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Accordingly, new claims can be formulated during prosecution of this application (or an application claiming priority thereto) to any such combination of features. In particular, with reference to the appended claims, features from dependent claims can be combined with those of the independent claims and features from respective independent claims can be combined in any appropriate manner and not merely in the specific combinations enumerated in the appended claims.

The following examples pertain to further embodiments. The various features of the different embodiments can be variously combined with some features included and others excluded to suit a variety of different applications.

Example embodiment 1: A solar cell includes a semiconductor region in or above a substrate. A metal foil portion has a top surface, a bottom surface, and a sidewall surface, the bottom surface having an adhesive layer thereon. The adhesive layer is above the semiconductor region and has an opening therein exposing a portion of the semiconductor region. A conductive material is on and electrically coupled to the portion of the semiconductor region exposed by the opening in the adhesive layer. The conductive material is further on and electrically coupled to the sidewall surface of the metal foil portion. In an embodiment, the conductive material can be on and in contact with the bottom surface of the metal foil.

Example embodiment 2: The solar cell of example embodiment 1, wherein the conductive material has a top surface substantially co-planar with the top surface of the metal foil portion.

Example embodiment 3: The solar cell of example embodiment 1 or 2, wherein the sidewall surface of the metal foil portion completely laterally surrounds the conductive material.

Example embodiment 4: The solar cell of example embodiment 1, 2 or 3, wherein the adhesive layer electrically isolates the bottom surface of the metal foil portion from the semiconductor region.

Example embodiment 5: The solar cell of example embodiment 1, 2, 3 or 4, wherein the adhesive layer is directly on the semiconductor region.

Example embodiment 6: The solar cell of example embodiment 1, 2, 3 or 4, further including an intervening layer (e.g., an anti-reflective coating material layer) between the adhesive layer and the semiconductor region.

Example embodiment 7: The solar cell of example embodiment 1, 2, 3, 4, 5 or 6, wherein the metal foil portion includes a copper foil portion or an aluminum foil portion.

Example embodiment 8: The solar cell of example embodiment 1, 2, 3, 4, 5, 6 or 7, wherein the conductive material is a conductive paste or a conductive seed material. In an embodiment, conductive material includes a metal selected from the group consisting of copper, aluminum, silver and tin.

Example embodiment 9: The solar cell of example embodiment 1, 2, 3, 4, 5, 6, 7 or 8, further including a conductive layer over the top surface of the metal foil portion, the conductive layer directly on and electrically coupled to the conductive material.

Example embodiment 10: The solar cell of example embodiment 9, wherein the conductive layer is directly on the top surface of the metal foil portion.

Example embodiment 11: The solar cell of example embodiment 9 or 10, wherein the conductive layer is or includes a solder paste.

Example embodiment 12: The solar cell of example embodiment 1, 2, 3, 4, 5, 6, 7, 8, 9, 10 or 11, wherein the semiconductor region is a polycrystalline silicon layer. In an embodiment, the polycrystalline layer is disposed on a thin dielectric layer on the substrate.

Example embodiment 13: The solar cell of example embodiment 1, 2, 3, 4, 5, 6, 7, 8, 9, 10 or 11, wherein the semiconductor region is a doped region of the substrate.

Example embodiment 14: The solar cell of example embodiment 1, 2, 3, 4, 5, 6, 7, 8, 9, 10, 11, 12 or 13, wherein a portion of the conductive material on the sidewall surface of the metal foil portion has a width approximately greater than a portion of the conductive material in the opening in the adhesive layer.

Example embodiment 15: A method of fabricating a solar cell includes locating a metal foil above a semiconductor region in or above a substrate, the metal foil having a bottom surface with an adhesive layer thereon. An etch mask is formed above the metal foil, the etch mask having an opening exposing a portion of the metal foil. The exposed portion of the metal foil is etched to form a metal foil portion having an opening exposing a portion of the adhesive layer. The etch mask is removed. The exposed portion of the adhesive layer is removed to form a patterned adhesive layer having an opening exposing a portion of the semiconductor region. A conductive material is formed in the opening of the metal foil portion and in the opening of the adhesive layer. The conductive material is on the exposed portion of the semiconductor region.

Example embodiment 16: The method of example embodiment 15, further including forming a conductive layer over a top surface of the metal foil portion and on the conductive material.

Example embodiment 17: The method of example embodiment 15 or 16, wherein removing the exposed portion of the adhesive layer involves using a laser ablation process.

Example embodiment 18: A method of fabricating a solar cell includes locating a pre-patterned metal foil above a semiconductor region in or above a substrate, the pre-patterned metal foil having a bottom surface with an adhesive layer thereon, and the pre-patterned metal foil having an opening exposing a portion of the adhesive layer. An etch mask is formed above the pre-patterned metal foil, the etch mask covering a portion of the pre-patterned metal foil and covering the opening in the pre-patterned metal foil, and the etch mask exposing another portion of the pre-patterned metal foil. The exposed portion of the pre-patterned metal foil is etched to form a metal foil portion. The etch mask is removed. The exposed portion of the adhesive layer is removed to form a patterned adhesive layer having an opening exposing a portion of the semiconductor region. A conductive material is formed in the opening of the metal foil portion and in the opening of the adhesive layer. The conductive material is on the exposed portion of the semiconductor region.

Example embodiment 19: The method of example embodiment 18, further including forming a conductive layer over a top surface of the metal foil portion and on the conductive material.

Example embodiment 20: The method of example embodiment 19, wherein removing the exposed portion of the adhesive layer involves using a laser ablation process.

1. A solar cell, comprising:
a semiconductor region in or above a substrate;
an adhesive layer disposed over the semiconductor region, wherein the adhesive layer comprises an opening exposing a portion of the semiconductor region;
a metal foil disposed on the adhesive layer; and
a conductive material on and electrically coupled to the portion of the semiconductor region exposed by the opening in the adhesive layer, the conductive material further in contact with and electrically coupled to a portion of the metal foil.

2. The solar cell of claim 1, wherein the adhesive layer electrically isolates the metal foil from the semiconductor region.

3. The solar cell of claim 1, further comprising:
an intervening layer disposed between the adhesive layer and the semiconductor region.

4. The solar cell of claim 3, wherein intervening layer comprises an opening in alignment with the opening in the adhesive layer, the opening in the intervening layer exposes the portion of the semiconductor region.

5. The solar cell of claim 3, wherein the intervening layer comprises a material selected from the group consisting of silicon oxide and silicon nitride.

6. The solar cell of claim 1, wherein the metal foil comprises a foil selected from the group consisting of a copper foil, aluminum foil, copper alloy foil, and aluminum alloy foil.

7. The solar cell of claim 1, wherein the conductive material comprises a metal selected from the group consisting of copper, aluminum, silver and tin.

8. The solar cell of claim 1, further comprising:
a conductive layer over the top surface of the metal foil portion, the conductive layer directly on and electrically coupled to the conductive material.

9. The solar cell of claim 9, wherein the conductive layer comprises a solder paste.

10. The solar cell of claim 1, wherein the semiconductor region is a polycrystalline silicon layer, the polycrystalline layer on a thin dielectric layer on the substrate.

11. A solar cell, comprising:
a semiconductor region in or above a substrate;
an adhesive layer disposed over the semiconductor region, wherein the adhesive layer comprises an opening;
a metal foil disposed on the adhesive layer, the metal foil comprising an opening in alignment with the opening in the adhesive layer, wherein the openings in the adhesive layer and metal foil both expose a portion of the semiconductor region; and
a conductive material on and electrically coupled to the portion of the semiconductor region exposed by the openings in the adhesive layer and the metal foil, the conductive material further in contact with and electrically coupled to a portion of the metal foil.

12. The solar cell of claim 11, wherein the metal foil comprises a top surface, a bottom surface, and a sidewall surface disposed along the opening in the metal foil.

13. The solar cell of claim 12, wherein the adhesive layer is above the semiconductor region and has an opening in alignment with the opening of the metal foil, the opening in the adhesive layer exposing a portion of the semiconductor region.

14. The solar cell of claim 12, wherein the conductive material is further on and electrically coupled to the sidewall surface of the metal foil.

15. A method of fabricating a solar cell, the method comprising:
locating a metal foil above a semiconductor region in or above a substrate, the metal foil having a bottom surface with an adhesive layer thereon;
forming an etch mask above the metal foil, the etch mask having an opening exposing a portion of the metal foil;
etching the exposed portion of the metal foil to form a metal foil portion having an opening exposing a portion of the adhesive layer;
removing the etch mask;
removing the exposed portion of the adhesive layer to form a patterned adhesive layer having an opening exposing a portion of the semiconductor region; and
forming a conductive material in the opening of the metal foil portion and in the opening of the adhesive layer, the conductive material on the exposed portion of the semiconductor region.

16. The method of claim 15, further comprising:
forming a conductive layer over a top surface of the metal foil portion and on the conductive material.

17. The method of claim 15, wherein removing the exposed portion of the adhesive layer comprises using a laser ablation process.

18. A method of fabricating a solar cell, the method comprising:
locating a pre-patterned metal foil above a semiconductor region in or above a substrate, the pre-patterned metal foil having a bottom surface with an adhesive layer thereon, and the pre-patterned metal foil having an opening exposing a portion of the adhesive layer;
forming an etch mask above the pre-patterned metal foil, the etch mask covering a portion of the pre-patterned metal foil and covering the opening in the pre-patterned metal foil, and the etch mask exposing another portion of the pre-patterned metal foil;
etching the exposed portion of the pre-patterned metal foil to form a metal foil portion;
removing the etch mask;
removing the exposed portion of the adhesive layer to form a patterned adhesive layer having an opening exposing a portion of the semiconductor region; and
forming a conductive material in the opening of the metal foil portion and in the opening of the adhesive layer, the conductive material on the exposed portion of the semiconductor region.

19. The method of claim 18, wherein removing the exposed portion of the adhesive layer comprises using a laser ablation process.

20. A method of fabricating a solar cell, the method comprising:
locating a pre-patterned metal foil above a semiconductor region in or above a substrate, the pre-patterned metal foil having a bottom surface with a pre-patterned adhesive layer thereon, and the pre-patterned metal foil and the pre-patterned adhesive layer having an opening exposing a portion of the semiconductor region;
forming an etch mask above the pre-patterned metal foil, the etch mask covering a portion of the pre-patterned metal foil and covering the opening in the pre-patterned metal foil and the pre-patterned adhesive layer, and the etch mask exposing another portion of the pre-patterned metal foil;
etching the exposed portion of the pre-patterned metal foil;
removing the etch mask; and
forming a conductive material in the opening of the pre-patterned metal foil and pre-patterned adhesive layer, the conductive material on the exposed portion of the semiconductor region.

21. The method of claim 20, wherein prior to locating a pre-patterned metal foil above a semiconductor region in or above a substrate, performing a mechanical drilling process on a metal foil and adhesive layer to form the pre-patterned metal foil and the pre-patterned adhesive layer.
